(19) United States
(12) Patent Application Publication
(10) Pub. No.: US 2013/0126774 A1
(43) Pub. Date: May 23, 2013

(54) PIEZOELECTRIC FOAM STRUCTURES AND HYDROPHONE UTILIZING SAME

(71) Applicant: The Research Foundation of State University of New York, Albany, NY (US)

(72) Inventors: T.A. VENKATESH, Port Jefferson, NY (US); Krishna Sri CHALLAGULLA, Sudbury (CA)

(73) Assignee: The Research Foundation of State University of New York, Albany, NY (US)

(21) Appl. No.: 13/680,993

(22) Filed: Nov. 19, 2012

Related U.S. Application Data
(60) Provisional application No. 61/561,085, filed on Nov. 17, 2011.
(60) Provisional application No. 61/561,097, filed on Nov. 17, 2011.
(60) Provisional application No. 61/561,103, filed on Nov. 17, 2011.

(51) Int. Cl. H01L 41/18

(52) U.S. Cl. CPC H01L 41/18
USPC 252/62.9 R

(57) ABSTRACT

Disclosed is a piezoelectric foam formed of elastically anisotropic materials. The piezoelectric foam is defined with a unit cell having a relative density and volume fraction, and deformation specified by subjecting the unit cell to controlled mechanical and electrical loading conditions. Resultant stress and electric displacements field components are measured by capturing a homogeneous coupled response of the unit cell and by computing piezoelectric material constants using the captured homogeneous coupled response, to identify asymmetric and symmetric F1, F2 and F3 type piezoelectric foam structures.

### PRIORITY

This application claims priority to U.S. Provisional Applications No. 61/561,085, 61/561,097 and 61/561,103, each filed Nov. 17, 2011, the contents of each of which are incorporated herein by reference.

### BACKGROUND OF THE INVENTION

1. Field of the Invention

The present invention relates generally to piezoelectric foam structures and hydrophone systems utilizing the same.

2. Description of the Related Art

Piezoelectric materials, e.g., lead zirconate titanate (PZT) and barium titanate, by virtue of their unique electromechanical coupling characteristics, play a prominent role in the modern electro-ceramic industry. Applications of piezoelectric materials include a variety of sensors, actuators and devices such as ultrasound imagers and hydrophones. The properties of monolithic piezoelectric materials can be enhanced via an additive approach of adding two or more constituents to create several types of piezoelectric composites. Such piezoelectric composites can be designed to exhibit improved mechanical flexibility and piezoelectric activity, and optimized for ultrasonic imaging. The properties of piezoelectric materials can also be modified via the subtractive approach by introducing controlled porosity in the matrix materials to create porous piezoelectric materials. Such porous piezoelectrics can be tailored to demonstrate improved signal-to-noise ratio, impedance matching, and sensitivity, and thus be optimized for applications such as hydrophone devices.

Shape, orientation, distribution, and connectivity of porosity in piezoelectric materials can significantly influence the performance characteristics of 3-1 type and 3-0 type porous piezoelectric materials. Accordingly, piezoelectric composites, such as those with zero-dimensional (0-3 type), one-dimensional (1-3 type), two-dimensional (2-2 type), and three-dimensional (3-3 type) connectivity, have been extensively studied by analytical modeling, numerical modeling and experimental characterization. Several analytical, numerical and experimental studies have also been conducted to understand the effects of zero-dimensional (3-0), one-dimensional (3-1) and three-dimensional (3-3) porosity on electromechanical response of porous piezoelectric materials.

Bast et al., Influence of Internal Voids with 3-1 Connectivity on the Properties of Piezoelectric Ceramics Prepared by a New Planar Process, Ferroelectrics, 94:229-242 (1989), synthesized 3-1 type porous piezoelectric materials and demonstrated that the acoustic impedance of such porous materials decreased with increased porosity. Nagata et al., Properties of Interconnected Porous Pb(Zr, Ti)O3 Ceramic, J. Appl. Phys, 19: L37-L40 (1980), synthesized PZT-based piezoelectric materials with 3-3 type interconnected porosity using a modified powder sintering method and demonstrated that 3-3 type porous materials exhibited improved hydrophone sensitivity and improved voltage output characteristics as compared to that of pore-free PZT materials. Kara et al., Porous PZT Ceramics for Receiving Transducers, IEEE Trans Ultrason. Ferroelectr. Freq. Control; 50:289-296 (2003), also demonstrated that hydrophones made from porous piezoelectric structures have better sensitivity than those made from PZT-polymer composites. Furthermore, Zhang et al., Microstructure and Electrical Properties of Porous PZT Ceramics Derived from Different Pore-Forming Agents, Acta Mater.; 55:171-181 (2007), studied electrical and acoustic properties of porous lead zirconate titanate (PZT) ceramics and Boumchedda et al., Properties of Hydrophone Produced With Porous PZT Ceramic, J. Eur. Ceram. Soc.; 27:4169-4171 (2007), studied PZT ceramics having spherical shaped and interconnected porosity for possible use in hydrophone applications and concluded that cellular ceramics with higher volume fraction of porosity exhibited better hydrostatic characteristics compared to porous ceramics with lower volume fraction of porosity.

Foam structures such as open-cell foams are typically visualized as a complex network of struts or ligaments that can be constructed from several types of building blocks that include cubic, tetrahedral, dodecahedral, and tetrakaidecahedral unit cells. In general, the structural properties of foams can be derived from an understanding of the structural response of the characteristic unit cells that are subjected to appropriate boundary conditions. Gibson and Ashby, Cellular Solids: Structures and Properties, Cambridge University Press (1997), presented a review on structural foams and developed a cubic unit cell-based model for three-dimensional open-cell foams. It has been shown that for low density solids, the Young's modulus (E*) of the foams can be related to their relative density (ρ) according to Equation (1):

$$\frac{{E}^{*}}{{E}_{s}} = {C ( \frac{{ρ}^{*}}{{ρ}_{s}} )}^{n} , \qquad ( 1 )$$

where ρ* is the density of the foam, Eₛ, and ρₛ are the Young's modulus and density of a solid strut, respectively. Constants C and n depend on the microstructure of the solid material and the value of n generally lies in the range 1≦n≦4. For open-cell foams, experimental results suggest that n=2 and C≈1.

In addition to the dependency of the properties of foam structures on their relative density/volume fractions, the mechanical properties of the foams are also dependent on the deformation mechanisms of the struts and the ligaments in the foam structure. For foams having ‘straight-through’ struts, mechanical deformation is assumed to occur along the axis of the struts and the mechanical properties are linearly related to the foam density. Alternately, if the struts have finite rigidity and deform in bending, then the structural properties are non-linearly related to the relative density of the foam. Li et al., Micromechanical Modeling of Three-Dimensional Open-Cell Foams Using the Matrix Method for Spatial Frames, Compos. Part B-ENG; 36:249-262 (2005), estimated the effective properties of a three-dimensional open-cell foam using a matrix method for spatial frames by assuming that the members undergo simultaneous axial, transverse shearing, flexural, and torsional deformation. Zhu et al., Analysis of the Elastic Properties of Open-Cell Foams with Tetrakaidecahedral Cells, J. Mech. Phys. Solids; 45:319-343 (1997), derived elastic constants for open-cell foams by considering bending, twisting, and extension of the cell edges. Zhu et al., Analysis of High Strain Compression of Open-Cell Foams, J. Mech. Phys. Solids; 45:1875-1904 (1997), analyzed buckling of elastic cell-edge under combined bending and torsional loads. More recently, Roy et al., General Tetrakaidecahedron Model for Open-Celled Foams, Int. J. Solids Struct.; 45:1754-1765 (2008), assumed that the cell-edges possess axial and bending rigidity, and developed an analytical model to predict the Young's modulus, Poisson's ratio and tensile strength of an elongated tetrakaidecahedron-based open-cell foam.

In addition to studies directed towards understanding the effects of the relative density and the deformation mechanisms of the strut elements on the properties of foams, efforts have been made to characterize the effects of cell shape, cell irregularity, and strut cross-section on the effective mechanical properties of foams. Li et al., Micromechanics Model for Three-Dimensional Open-Cell Foams Using Tetrakaidecahedral Unit Cell and Castigliano's Second Theorem, Compos. Sci. Tech.; 63:1769-1781 (2003), used an energy method based on Castigliano's second theorem to predict the effective Young's modulus and the Poisson's ratio of open-cell foams using a tetrakaidecahedral unit cell by considering three deformation mechanisms, i.e., stretching, shearing, and bending, for struts elements with several cross-sectional shapes, i.e., circular, square, triangular, and plateau border.

In addition to analytical models, numerical models based on idealized unit cells have been developed to predict effective mechanical properties and creep behavior of open-cell metallic foams as well as the crush behavior of closed-cell metallic foams. Furthermore, Demiray et al., Numerical Determination of Initial and Subsequent Yield Surfaces of Open-Celled Model Foams, J. Int. J. Solids Struct.; 44:2093-2108 (2007), studied overall yield behavior of foam structures using a combination of microstructural modeling and numerical homogenization techniques.

While much recent work has focused on understanding the properties of metallic foams, few efforts have also been made to understand and characterize the structural properties of ceramic foams as well. Among these few efforts are Salazar et al., Compression Strength and Wear Resistance of Ceramic Foams-Polymer Composites, Mater. Lett.; 60:1687-1692 (2006), who analyzed the influence of pore density and the wettability of a polymer on mechanical properties of ceramic foams-polymer composites and observed an improvement in compression strength of ceramic foams-polymer composites compared to ceramic materials without polymer infiltration.

Overall, several studies have indicated that porous piezoelectric materials, particularly of the 3-3 type open architecture made from elastically anisotropic materials, could exhibit useful electromechanical properties. Several studies have also provided frameworks to understand the mechanical properties of 3-3 type foam materials made from elastically isotropic metallic/ceramic materials, as shown in Table I, which provides a summary of analytical and numerical models developed to predict the mechanical response of open-cell foams.

TABLE I

| Study | Model | Strut material | Assumed strut deformation |
|---|---|---|---|
| Gibson and Ashby, | Analytical model | Isotropic | Bending |
| See Section 5.3 | | | |
| Christensen, J. Mech Phys | Analytical model | Isotropic | Axial |
| Solids; 34: 563-578 (1986) | | | |
| Li et al., Compos Part B-ENG; | Analytical model | Isotropic | Simultaneous axial, |
| 36: 249-262 (2005) | | | transverse shearing, flexural |
| | | | and torsional deformation |
| Zhu et al., J. Mech Phys | Analytical model | Isotropic | Bending, twisting and |
| Solids; 45: 319-343 (1997) | | | extension |
| Sihn and Roy, J. Mech Phys | Numerical model | Isotropic | Bending and shear |
| Solids; 52: 167-191 (2004) | | | |
| Oppenheimer and Dunand, | Numerical model | Isotropic | Bending, axial, combination |
| Acta Mater; 55: 3825-3834 | | | of bending and axial, double |
| (2007) | | | bending |

However, a comprehensive study of the electromechanical properties of piezoelectric foam structures for synthesis from elastically anisotropic materials is not provided by conventional studies or systems. Accordingly, the present invention provides a numerical model based analysis of piezoelectric materials that is based on modeling of a combination of bending and axial deformation of the piezoelectric struts.

### SUMMARY OF THE INVENTION

The present invention overcomes the above shortcoming of conventional methods and systems and provides a piezoelectric foam formed of elastically anisotropic materials. The piezoelectric foam includes a unit cell of an elastically anisotropic material having a relative density/volume fraction and specified deformation that are specified by subjecting the unit cell to controlled mechanical and electrical loading conditions. Resultant stress and electric displacements field components are measured by capturing a homogeneous coupled response of the unit cell, and by computing piezoelectric material constants using the captured homogeneous coupled response, to identify type F1, F2 and F3 piezoelectric foam structures.

### BRIEF DESCRIPTION OF THE DRAWINGS

The above and other objects, features and advantages of certain exemplary embodiments of the present invention will be more apparent from the following detailed description taken in conjunction with the accompanying drawings, in which:

FIGS. 1(a)-1(d) illustrate 3-3 type piezoelectric foam structures, with FIG. 1(a) showing asymmetric interconnection of type F1 piezoelectric foam structures of the present invention, FIG. 1(b) showing symmetric interconnection of type F2 piezoelectric foam structures of the present invention, FIG. 1(c) showing lack of interconnects of F3 type foam structures of the present invention, and FIG. 1(d) showing a conventional 3-1 (type F4 foam structure formed of long porous structures;

FIGS. 2(a)-(d) provide schematic representations of the type F1 piezoelectric foam of the present invention, with asymmetric interconnect details;

FIGS. 3(a)-(d) provide schematic representations of a type F2 piezoelectric foam of the present invention, with symmetric interconnect details;

FIGS. 4(a)-(b) provide graphs of Young's modulus and shear modulus comparing F1 and F3 type foam structures of the present invention with foam structures identified by conventional models;

FIGS. 5(a)-(d) show spatial evolution of stresses (Pa) in a type F1 piezoelectric foam structure of the present invention upon application of mechanical strain;

FIGS. 6(a)-(p) are graphs comparing fundamental elastic, piezoelectric, and dielectric properties of the F1, F2 and F3 type piezoelectric foam structures of the present invention to conventional F4 type long-porous piezoelectric materials;

FIGS. 7(a)-7(f) are schematic representations of closely-packed and sparsely-packed F1 type piezoelectric foam structures of the present invention;

FIGS. 8(a)-(p) are graphs comparing fundamental elastic, piezoelectric, and dielectric properties of the F1, F2 and F3 type piezoelectric foam structures as a function of interconnect lengths and volume fraction; and

FIGS. 9(a)-(j) are graphs showing variation of select figures of merit of piezoelectric foam structures F1, F2 and F3 of the present invention to conventional F4 type long-porous piezoelectric materials.

### DETAILED DESCRIPTION OF THE EMBODIMENTS

The following detailed description of embodiments of the invention will be made in reference to the accompanying drawings. In describing the invention, explanation of related functions or constructions known in the art are omitted for the sake of clarity in understanding the concept of the invention that would otherwise obscure the invention with unnecessary detail.

Set forth below are a classification of porous piezoelectric foam structures, a description of constitutive relationships describing coupled behavior of piezoelectric materials, details of the finite element based numerical models developed in the present invention to characterize the electromechanical properties of piezoelectric foam structures, and improvements in electromechanical properties of piezoelectric foams structures.

In general, porous piezoelectric materials are classified into three distinct types: (i) 3-0 type, where the porosity is enclosed in all three dimensions by a matrix phase; (ii) 3-1 type, where the porosity exhibits connectivity in the 1-direction, which is similar to the case of long fibers embedded in the continuous matrix phase, which is connected to itself in all three directions; and (iii) 3-3 type, where the porosity exists in an open inter-connecting network where both the matrix phase and the porosity exhibit connectivity in all three directions of foam structures.

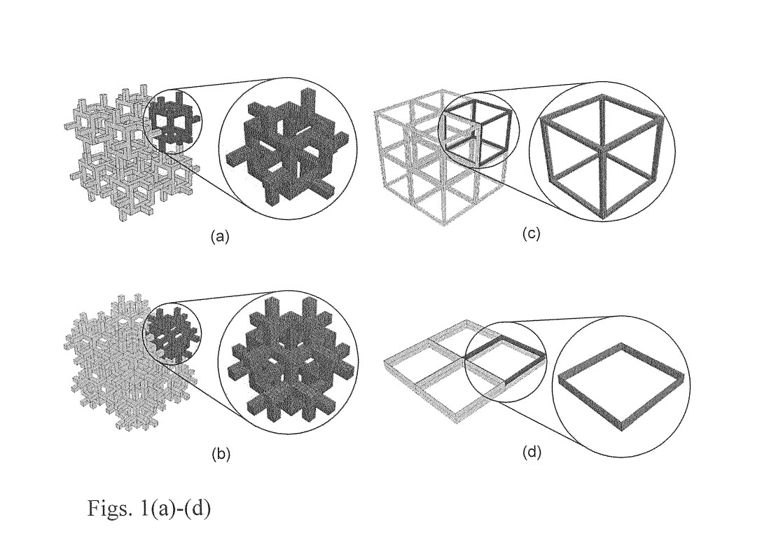

In the present invention, the effective electromechanical response of three types of piezoelectric foam structures, i.e., 3-3 type structures designated as F1, F2 and F3, with and without interconnecting struts of two types of interconnect geometry and of varying interconnect lengths are benchmarked with respect to that of piezoelectric materials with long pores, i.e., 3-1 type, designated as F4, which is shown in FIG. 1(d) with the poling axis aligned with the 2-direction.

The foam structures identified in the present invention are different from those investigated by Boumchedda et al., Properties of Hydrophone Produced With Porous PZT Ceramic, J. Eur. Ceram. Soc.; 27:4169-4171 (2007), which considered PZT ceramics that contained spherical shaped porosity arranged in a non-periodic manner. In contrast, the piezoelectric foams of the present invention have cuboidal shaped porosity arranged in a regular, periodic manner. Furthermore, the piezoelectric foams of the present invention contain symmetric or asymmetric interconnects, as well as porosity without any interconnects.

The electromechanical coupled constitutive relationships for piezoelectric materials of the present invention are provided by Equation (2):

σᵢⱼ=Cᵢⱼₖₗ^{E}∈ₖₗ−eᵢⱼₖEₖ

Dᵢ=eᵢₖₗ∈ₖₗ+κᵢⱼ^{∈}Eⱼ (2)

, where σ and ∈ are the second-order stress and strain tensors, respectively, E is the electric field vector, D is the electric displacement vector, C^{E} is the fourth-order elasticity tensor with superscript “E” indicating that the elasticity tensor corresponds to measurement of C at constant or zero electric field, e is the third-order coupling tensor, and κ^{∈} is the second-order permittivity tensor measured at constant or zero strain.

Equation (2) can be represented by a matrix using the following mapping of adjacent indices: 11→1, 22→2, 33→3, 23→4, 13→5, 12→6, as Equation (3):

$$( \begin{matrix}{σ}_{11} \\ {σ}_{22} \\ {σ}_{33} \\ {σ}_{23} \\ {σ}_{13} \\ {σ}_{12} \\ {D}_{1} \\ {D}_{2} \\ {D}_{3}\end{matrix} ) = ( \begin{matrix}{C}_{11}^{E} & {C}_{12}^{E} & {C}_{13}^{E} & {C}_{14}^{E} & {C}_{15}^{E} & {C}_{16}^{E} & - {e}_{11} & - {e}_{21} & - {e}_{31} \\ … & {C}_{22}^{E} & {C}_{23}^{E} & {C}_{24}^{E} & {C}_{25}^{E} & {C}_{26}^{E} & - {e}_{12} & - {e}_{22} & - {e}_{32} \\ … & … & {C}_{33}^{E} & {C}_{34}^{E} & {C}_{35}^{E} & {C}_{36}^{E} & - {e}_{13} & - {e}_{23} & - {e}_{33} \\ … & … & … & {C}_{44}^{E} & {C}_{45}^{E} & {C}_{46}^{E} & - {e}_{14} & - {e}_{24} & - {e}_{34} \\ … & … & … & … & {C}_{55}^{E} & {C}_{56}^{E} & - {e}_{15} & - {e}_{25} & - {e}_{35} \\ … & … & … & … & … & {C}_{66}^{E} & - {e}_{16} & - {e}_{26} & - {e}_{36} \\ {e}_{11} & {e}_{12} & {e}_{13} & {e}_{14} & {e}_{15} & {e}_{16} & {κ}_{11}^{ɛ} & {κ}_{12}^{ɛ} & {κ}_{13}^{ɛ} \\ {e}_{21} & {e}_{22} & {e}_{23} & {e}_{24} & {e}_{25} & {e}_{26} & … & {κ}_{22}^{ɛ} & {κ}_{23}^{ɛ} \\ {e}_{31} & {e}_{32} & {e}_{33} & {e}_{34} & {e}_{35} & {e}_{36} & … & … & {κ}_{33}^{ɛ}\end{matrix} ) ( \begin{matrix}{ɛ}_{11} \\ {ɛ}_{22} \\ {ɛ}_{33} \\ 2 {ɛ}_{23} \\ 2 {ɛ}_{13} \\ 2 {ɛ}_{12} \\ {E}_{1} \\ {E}_{2} \\ {E}_{3}\end{matrix} ) \qquad ( 3 )$$

As represented by (.) in Equation (3), the elastic, piezoelectric and dielectric coefficients are symmetric about the diagonal. Equation (3) is the most general representation of the constitutive relationship and has twenty-one elasticity, eighteen piezoelectric and six permittivity constants that are independent material properties. Thus, a complete characterization of piezoelectric foam in the linear elastic domain requires an identification of all forty-five material constants.

In assessing the utility of piezoelectric materials for practical applications, several combinations of the fundamental material constants, i.e., figures of merit, are typically invoked. Four figures of merit of direct interest to piezoelectric foams and applications thereof, e.g., hydrophones, are the piezoelectric charge coefficient (dₕ), the hydrostatic figure of merit (dₕgₕ), the acoustic impedance (Z), and the coupling constant (kₜ), as typically invoked to characterize the utility of porous piezoelectric materials in practical applications. See, Kar-Gupta, et al., Electromechanical Response of Porous Piezoelectric Materials, Acta Mater; 54:4063-4078 (2006).

The piezoelectric charge coefficient (dₕ=d₂₂+d₂₁+d₂₃), captures the effective strength of electro-mechanical coupling in a piezoelectric material, especially in the conversion of mechanical loads under hydrostatic loading conditions to electrical signals in a given direction, i.e., a poling direction).

In applications such as in hydrophones, large values of the piezoelectric charge coefficient are desirable in order to achieve enhanced sensitivity to the detection of sound waves. The charge coefficients (d) are related to the coupling constants (e) as in Equation (4):

eₙᵢⱼ=dₙₖₗCₖₗᵢⱼ^{E} (4)

In general, an important design consideration for transducers is the signal-to-noise ratio, which is determined by the spectral noise pressure ( p̅_̅{̅H̅}̅²̅) given by Equation (5):

$$\overline{{p}_{H}^{2}} = \frac{4 kT \vert {Z}_{H} \vert {R}_{θ} tan δ}{{M}^{2}} \qquad ( 5 )$$

, where k is the Boltzman constant, T is the absolute ambient temperature, Z_{H} is the complex impedance of the hydrophone, R_{θ} is a directivity factor, tan δ is a dielectric loss factor, and M is hydrophone sensitivity.

When the hydrophone is in contact with acoustic pressure fields in all three directions; when the operating frequencies are low; and when the system operates well below mechanical resonance, Equation (5) reduces to Equation (6):

$$\overline{{p}_{H}^{2}} = \frac{4 kT tan δ}{ω {Vd}_{h} {g}_{h}} , \qquad ( 6 )$$

where gₕ=dₕ/κ₂₂. As evident from Equation (6), in order to enhance the signal-to-noise ratio, the spectral noise pressure must be minimized, i.e., the hydrostatic figure of merit (dₕgₕ) should be maximized.

The acoustic impedance (Z=(C₂₂^{D}ρ)^{1/2}) modulates the extent of signal transmission or reflection at the hydrophone/environment interface, where ρ is the density of the material. In order to enhance the performance of the hydrophone, good impedance matching between the hydrophone and the surrounding media, such as water which exhibits low inherent impedance, is desired. With densities lower than that of the pore-free material, porous piezoelectric materials have lower acoustic impedances and thus are targeted for hydrophone applications.

The piezoelectric coupling constant (kₜ=\sqrt{1−C₂₂^{E}/C₂₂^{D}}) represents the efficiency of energy conversion between the electrical and mechanical domains, with systems exhibiting larger coupling constants (ideally ˜1) being more desirable. The method of finite element modeling developed to capture the electromechanical response of piezoelectric foam structures is described below.

A unit-cell based three-dimensional finite element model is provided to characterize the electromechanical response of F1, F2 and F3 kinds of 3-3 type piezoelectric foam structures over a range of volume fractions and interconnect strut geometries is performed using a commercially available software, e.g., ABAQUS. The interconnect strut geometries generally limits the range of porosity volume fractions considered for ultra-low density piezoelectric foam structures of the present invention ranges between 70% and nearly 97%. Eight-node, linear piezoelectric brick elements (C3D8E) are utilized for the piezoelectric foam structures where each node is allowed four degrees of freedom, i.e., three translational degrees of freedom and one electric potential degrees of freedom.

The method of modeling to predict the properties of piezoelectric foams involves the following five steps: (i) a unit cell that is appropriate for a foam structure with a specified relative density/volume fraction and deformation is identified; (ii) the unit cell is subjected to controlled mechanical and electrical loading conditions under defined boundary conditions; (iii) the stress and electric displacements field components that developed in the unit cell as a result of applied strain and electric fields on the unit cell are measured; (iv) a homogeneous coupled response of the unit cell are captured; and (v) using the matrix representation of the coupled response of piezoelectric materials, where the measured stress and electric displacements are related to the imposed strain and electric fields through the constitutive material property matrix, all the piezoelectric material constants are computed.

In invoking the unit cell approach for characterizing the electromechanical behavior of piezoelectric foam structures, it is important to ensure that the deformation characteristics of the microscopic unit-cells are representative of the deformation of the macroscopic foam structures. Hence, the deformation across the boundaries of the representative unit cell should be compatible with the deformation of the adjacent unit cells. By comparing the deformation behavior of a microscopic unit cell with the macroscopic structure comprised of eight unit cells under several loading conditions, e.g., face loading, corner loading, and line loading, a set of loading and boundary conditions that provide the best estimates for all the electromechanical properties of the piezoelectric foam structures are identified. For a face loading condition, all the nodes on each face of the strut are loaded. In the corner loading condition, all the corner nodes on each face of the strut are loaded and, for an in line loading condition, all the nodes on the middle line of each face of the struts are loaded. The results of the finite element model are dependent on the interconnect geometry and porosity volume fraction, but are scale independent, i.e., independent of pore size.

Piezoelectric Foam Structure with Asymmetric Interconnects—F1

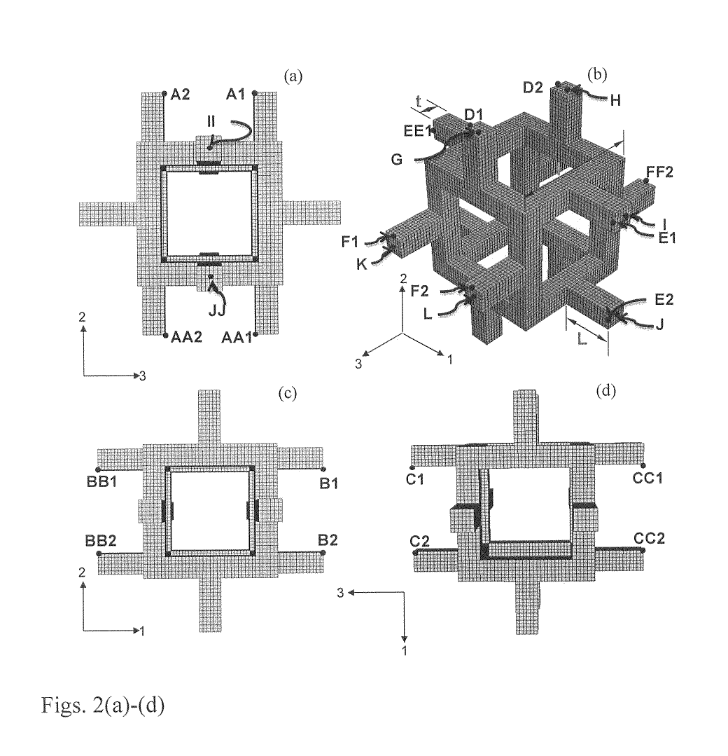

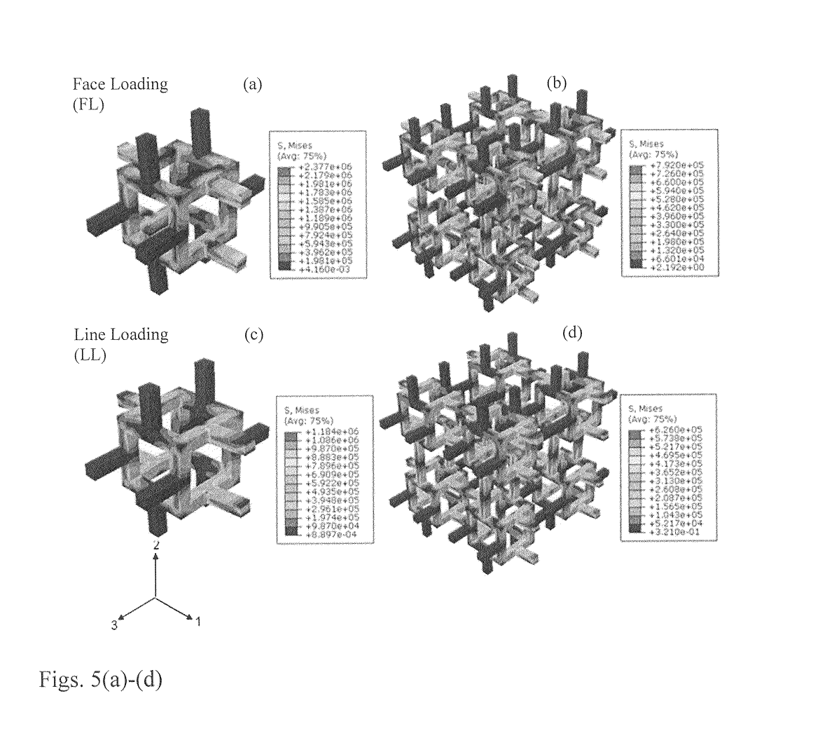

To ensure compatibility of deformation across unit-cell boundaries, the following constraint equations are identified for the piezoelectric foam structures shown in FIG. 1(a), with details of asymmetric interconnecting struts (F1) shown in FIGS. 2 and 5.

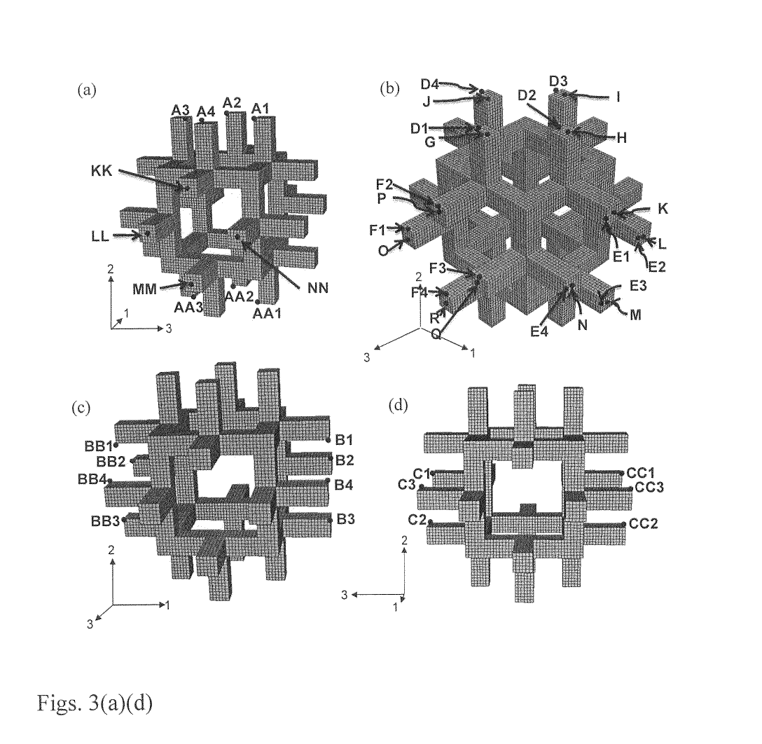

For compatibility in deformation along the 1-direction: u^{I}−u^{S1}=u^{II}−u^{SS1}, u^{J}−u^{S2}=u^{JJ}−u^{SS2}, where ‘u’ refers to all the translational and electric potential degrees of freedom; superscripts (I, II, J, JJ) shown in FIGS. 2-3 represent nodes on each respective face of the unit cell, superscripts (S1, SS1, S2, SS2) represent master nodes (B1, BB1, B2, BB2) for face loading and corner loading conditions and (E1, EE1, E2, EE2) represent master nodes for line loading condition. In FIGS. 2-3, H, HH, I, II, J, JJ, K, KK, L AND LL represent nodes on the unit-cell surfaces and A1, AA1, A2, AA2, B1, BB1, B2, BB2, C1, CC1, C2, CC2, D1, DD1, D2, DD2, E1, EE1, E2, EE2, F1, FF1, F2 AND FF2 represent Master Nodes on the unit-cell surfaces.

For compatibility in deformation along the 2-direction: u^{G}−u^{T1}=u^{GG}−u^{TT1}, u^{H}−u^{T2}=u^{HH}−u^{TT2}, where ‘u’ refers to all the (translational and electric potential) degrees of freedom; superscripts (G, GG, H, HH) represent all the nodes on each respective face of the unit cell, (T1, TT1, T2, TT2) represent master nodes (A1, AA1, A2, AA2) for face loading and corner loading conditions and (D1, DD1, D2, DD2) represent master nodes for line loading condition.

For compatibility in deformation along the 3-direction: u^{K}−u^{U1}=u^{KK}−u^{UU1}, u^{L}−u^{U2}=u^{LL}−u^{UU2}, where ‘u’ refers to all translational and electric potential degrees of freedom; superscripts (L, LL, K, KK) represent the nodes on each respective face of the unit cell, (U1, UU1, V1, VV1) represent master nodes (C1, CC1, C2, CC2) for face loading and corner loading conditions and (F1, FF1, F2, FF2) represent master nodes for line loading condition.

Accordingly, the unit-cell of FIGS. 2 (a)-(d) provide master nodes that control overall behavior of the unit cells, with FIGS. 2(a)-(d) providing visualization of the unit-cell from four different geometric points of view.

Piezoelectric Foam Structure with Symmetric Interconnects—F2

To ensure compatibility of deformation across the boundaries of the unit-cell, the following constraint equations are identified for the piezoelectric foam structure with symmetric interconnecting struts (F2), as shown in FIGS. 3(a)-(d).

For compatibility in deformation along the 1-direction: u^{K}−u^{S1}=u^{KK}−u^{SS1}, u^{L}−u^{S2}=u^{LL}−u^{SS2}, u^{M}−u^{S3}=u^{MM}−u^{SS3}, u^{N}−u^{S4}=u^{NN}−u^{SS4}, where ‘u’ refers to all the (translational and electric potential) degrees of freedom; superscripts (K, KK, L, LL, M, MM, N, NN) represent all the nodes on each respective face of the unit cell, (S1, SS1, S2, SS2, S3, SS3, S4, SS4) represent master nodes (B1, BB1, B2, BB2, B3, BB3, B4, BB4) for face loading and corner loading conditions and (E1, EE1, E2, EE2, E3, EE3, E4, EE4) represent master nodes for line loading condition. In FIGS. 3(a)-(d), G, GG, H, HH, I, II, J, JJ, K, KK, L, LL, M, MM, N, NN, O, OO, P, PP, Q, QQ, R and RR represent nodes on the unit-cell surfaces, and A1, AA1, A2, AA2, A3, AA3, A4, AA4, B1, BB1, B2, BB2, B3, BB3, B4, BB4, C1, CC1, C2, CC2, C3, CC3, C4, CC4, D1, DD1, D2, DD2, D3, DD4, D4, DD4, E1, EE1, E2, EE2, E3, EE3, E4, EE4, F1, FF1, F2, FF2, F3, FF3, F4 and FF4 represent Master Nodes on the unit-cell surfaces.

For compatibility in deformation along the 2-direction: u^{G}−u^{T1}=u^{GG}−u^{TT1}, u^{H}−u^{T2}=u^{HH}−u^{TT2}, u^{I}−u^{T3}=u^{II}−u^{TT3}, u^{J}−u^{T4}=u^{JJ}−u^{TT4}, where ‘u’ refers to all translational and electric potential degrees of freedom, superscripts (G, GG, H, HH, I, II, J, JJ) represent all the nodes on each respective face of the solids, (T1, TT1, T2, TT2, T3, TT3, T4, TT4) represent master nodes (A1, AA1, A2, AA2, A3, AA3, A4, AA4) for face loading and corner loading conditions and (D1, DD1, D2, DD2, D3, DD3, D4, DD4) represent master nodes for line loading condition.

For compatibility in deformation along the 3-direction: u^{O}−u^{U1}=u^{OO}−u^{UU1}, u^{P}−u^{U2}=u^{PP}−u^{UU2}, u^{Q}−u^{U3}=u^{QQ}−u^{UU3}, u^{R}−u^{U4}=u^{RR}−u^{UU4}, where ‘u’ refers to all translational and electric potential degrees of freedom, superscripts (O, OO, P, PP, Q, QQ, R, RR) represent all the nodes on each respective face of the solids, (U1, UU1, U2, UU2, U3, UU3, U4, UU4) represent master nodes (C1, CC1, C2, CC2, C3, CC3, C4, CC4) for face loading and corner loading conditions and (F1, FF1, F2, FF2, F3, FF3, F4, FF4) represent master nodes for line loading condition.

Similarly, the present invention facilitates identification of boundary conditions to model 3-3 type interconnect-free piezoelectric foam structures (F3) and 3-1 type long-porous piezoelectric materials (F4).

As discussed by Lewis et al., Microstructural Modeling of Polarization and Properties of Porous Ferroelectrics, Smart Mater Struct.; 20:085002 (2011), when an unpoled porous piezoelectric material is subjected to an external electric field in the poling process, some regions inside the material may remain unpoled if the local electric fields are less than the coercive field required for poling or poled in a direction that is different from the direction of the applied electric field if the local electric field is greater than the coercive field in an alternate direction. This non-uniformity in poling can be attributed to non-uniform electric fields generated inside the porous piezoelectric material because of the presence of two phases, i.e., solid and air, with a large difference in respective dielectric constants. In the present invention, the idealized scenario is considered where all regions of the piezoelectric material are considered as having been poled in the direction of the externally applied electric field. From a practical point of view, the idealized scenario can be realized by selecting an applied electric field large enough to polarize the entire material, but smaller than the electric field limit that causes dielectric breakdown, or small sample sizes are maintained.

The numerical model of the present invention is applied to foams with asymmetric interconnecting strut structures (F1) and the interconnect-free foam structure (F3) where the constituent elements of the foam structures are made of isotropic (non-piezoelectric) materials. Upon verifying that the results from the numerical model are in agreement with the analytical models developed earlier for isotropic, non-piezoelectric, materials, the finite element model is applied to piezoelectric foams, which can be elastically anisotropic and piezoelectric, to predict fundamental electromechanical properties and corresponding figures of merits. The properties of 3-3 piezoelectric foams are benchmarked with those of 3-1 type long-porous piezoelectric materials (F4) as well. PZT-7A is selected as a model material to illustrate improvements obtained in the piezoelectric foam structures of the present invention. Table II shows fundamental elastic, dielectric, and piezoelectric properties of the model material PZT-7A. Those of skill in the art will recognize that the model can be adapted to other piezoelectric materials.

TABLE II

| | PZT-7A |
|---|---|
| | (ρ = 7700 kg/m³) |
| C₁₁^{E} = C₃₃^{E} (GPa) | 148 |
| C₁₂^{E} = C₂₃^{E} (GPa) | 74.2 |
| C₁₃^{E} (GPa) | 76.2 |
| C₂₂^{E} (GPa) | 131 |
| C₄₄^{E} = C₆₆^{E} (GPa) | 25.3 |
| C₅₅^{E} (GPa) | 35.9 |
| e₂₁ = e₂₃ (C/m²) | −2.324 |
| e₂₂ (C/m²) | 10.9 |
| e₃₄ = e₁₆ (C/m²) | 9.31 |
| κ₁₁^{ε} = κ₃₃^{ε} (nC/Vm) | 3.98 |
| κ₂₂^{ε} (nC/Vm) | 2.081 |

### Analytical Verification of Numerical Modeling

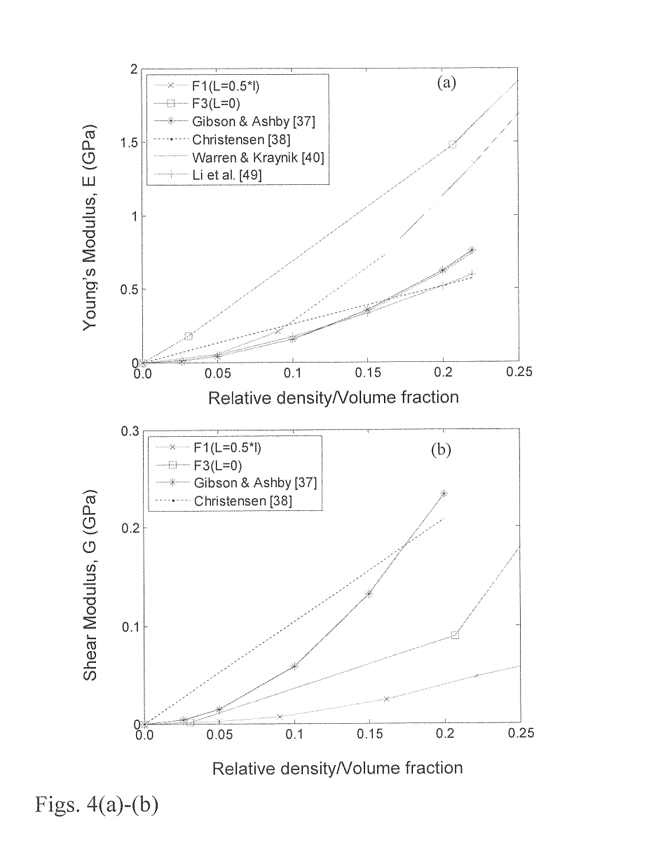

FIGS. 4(a)-(b) provide graphs comparing the Young's modulus and shear modulus computed from the finite element model developed according to the method described herein for the F1 foam structure with external strut length equal to half the internal cube dimension (L=0.5*1) (FIG. 2(b)) and for the foam structure F3 with external strut length equal to zero (L=0).

As shown in FIGS. 4(a)-(b), “37” refers to analytical models of Gibson and Ashby, “40” refers to conventional analytical models of Warren and Kraynik, assuming that the struts undergo only bending deformation whereas the conventional model of Christensen “38” assumes that the struts undergo axial deformation (compression), while the conventional model of Li et al. “49” considers three deformation mechanisms, i.e., stretching, shearing and bending. However, the finite element model of the present invention can accommodate simultaneous bending and axial deformation. Hence, the shear modulus predicted by the finite element model is generally lower than that predicted by conventional models such as Gibson and Ashby, as well as Christensen. In general, the finite element model of the present invention provides a more accurate prediction of the properties of the open cell foam structures that are available from conventional modeling techniques.

### Identifying Optimum Unit-Cell Boundary Conditions and Loading Conditions

Table III provides a comparison of structural properties obtained from simulations of a microscopic unit cell with that of a macroscopic foam structure with eight unit cells for the foam structure F1 of the present invention with a 5% material volume fraction, i.e., 95% porosity,) with external strut length equal to half the internal cube dimension (L=0.5*1) for three loading conditions, i.e., Face Loading (FL), Line Loading (LL), and Corner Loading (CL).

TABLE III

| Property | Unit cell | Foam structure | Unit cell | Foam structure |
|---|---|---|---|---|
| C₁₁(MPa) | 359.68(FL) | 365.58(FL) | 359.42(LL) | 365.44(LL) |
| C₁₂(MPa) | 8.7129(FL) | 8.7755(FL) | 8.7111(LL) | 8.775(LL) |
| C₁₃(MPa) | 9.8564(FL) | 9.798(FL) | 9.8421(LL) | 9.7942(LL) |
| C₂₂(MPa) | 329.64(FL) | 333.607(FL) | 328.9(LL) | 333.22(LL) |
| C₃₃(MPa) | 326.28(FL) | 330.88(FL) | 325.93(LL) | 330.76(LL) |
| C₂₃(MPa) | 9.903(FL) | 10.002(FL) | 9.8972(LL) | 10.1427(LL) |
| C₄₄(MPa) | 30.69(FL) | 16.87(FL) | 9.7335(LL) | 10.7365(LL) |
| C₅₅(MPa) | 33.28(FL) | 16.95(FL) | 9.6449(LL) | 10.5874(LL) |
| C₆₆(MPa) | 32.657(FL) | 17.37(FL) | 10.003(LL) | 10.9801(LL) |
| e₂₁(C/m²) | −0.000096(FL) | −0.0001376(FL) | −0.000103(LL) | −0.000141(LL) |
| e₂₂(C/m²) | 0.05369(FL) | 0.05429(FL) | 0.054188(LL) | 0.05476(LL) |
| e₂₃(C/m²) | 0.000673(FL) | 0.0004077(FL) | 0.0005937(LL) | 0.0003722(LL) |
| e₁₆(C/m²) | 0.0111(FL) | 0.00562(FL) | 0.00324(LL) | 0.003423(LL) |
| κ₁₁(C/Vm) | 1.84E−10(FL) | 2.96E−10(FL) | 1.41E−10(CL) | 2.07E−10(CL) |
| κ₂₂(C/Vm) | 1.188E−10(FL) | 2.0962E−10(FL) | 8.999E−10(CL) | 1.484E−10(CL) |
| κ₃₃(C/Vm) | 1.616E−10(FL) | 2.7034E−10(FL) | 1.254E−10(CL) | 1.895E−10(CL) |

FIGS. 5(a)-(d) show spatial evolution of stresses (Pa) in the F1 type piezoelectric foam structure of the present invention upon application of a mechanical strain, i.e., 25 micro strain, along the 2-direction on face 1 for single unit cell with interconnect length=0.5*inner cube dimension and multiple unit cells for two kinds of loading conditions, i.e., face loading and line loading. FIG. 5 compares the stresses developed in the foam structure F1 upon the application of a mechanical strain along the 2-direction on face 1 of the unit cell structure and the macroscopic foam structure under different boundary conditions.

Face loading conditions are used to characterize the fundamental properties C11, C12, C13, C22, C33, C23, e21, e22, and e23, line loading conditions are also used to characterize the properties C44, C55, C66, and e16, and corner boundary conditions characterize dielectric constants κ11, κ22, and κ33 as these loading conditions provide a best match between the properties obtained from the microscopic unit cell and the macroscopic foam structure.

### Piezoelectric Foam Structure Electromechanical Response

From the finite element analysis of a variety of piezoelectric foam structures, with and without interconnects, respectively, F1, F2 and F3 structures and the long-porous F4 structure, the following observations are made. In general, a majority of the elasticity constants (with the exception of C55 and C13) of the 3-3 open foam structures (F1, F2 and F3) tend to be lower than that of the 3-1 long-porous structure (F4). The longitudinal dielectric constant κ₂₂ of the 3-3 open foam structures is also lower than that of the long-porous structure while the transverse dielectric constants (κ₁₁ and κ₃₃) are higher in the open foam structures. The longitudinal piezoelectric constant e22 and other constants e₂₁, e₂₃, and e₁₆ of the 3-3 open foam structure are also lower than that of the long-porous structure. The normal elastic constants such as C₁₁, C₂₂ and C₃₃ are very similar for structures F1 and F2. However, the shear constants such as C₁₂, C₁₃ and C₂₃ of the F2 structure are higher than that of the F1 structure. The longitudinal and transverse dielectric constants of the F2 structure are marginally higher than that of the F1 structure. The piezoelectric constants e₂₂ and e₁₆ of the F1 and F2 structures are very similar over a range of volume fractions. However, the F2 structure exhibits higher piezoelectric constants e₂₁ and e₂₃ over a limited range of volume fractions. Several electromechanical constants (such as C₁₁, C₂₂, C₃₃, e₁₆ and e₂₂) of the F3 foam structure are higher than that of the F1 and F2 structure but lower than that of the F4 structure. The lowest longitudinal dielectric constants κ₁₁ and the highest transverse dielectric constants are exhibited by the F3 foam structure over a range of volume fractions.

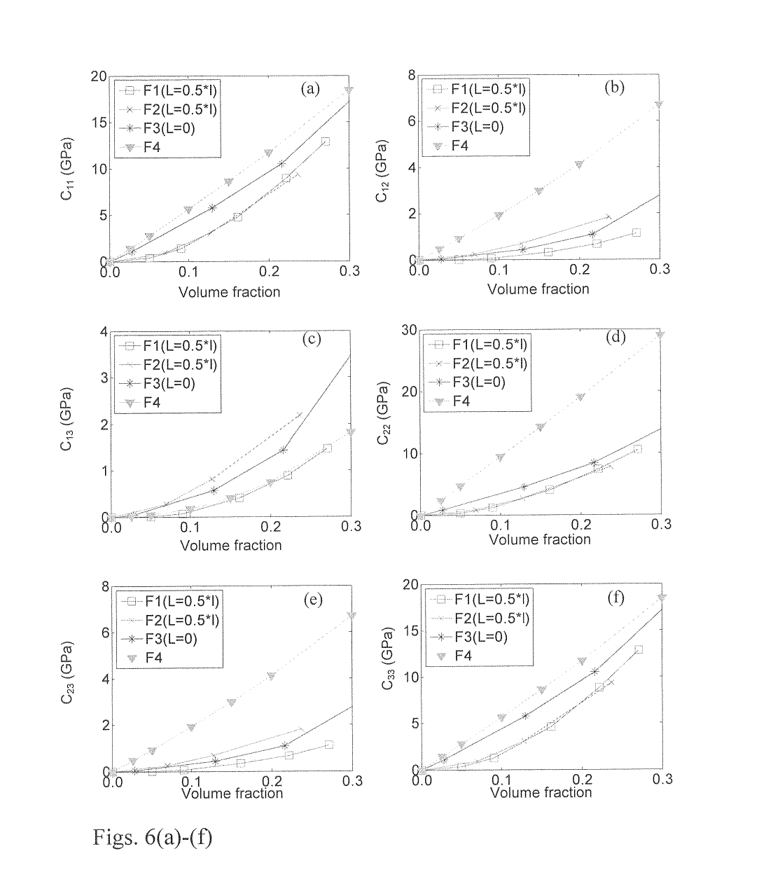

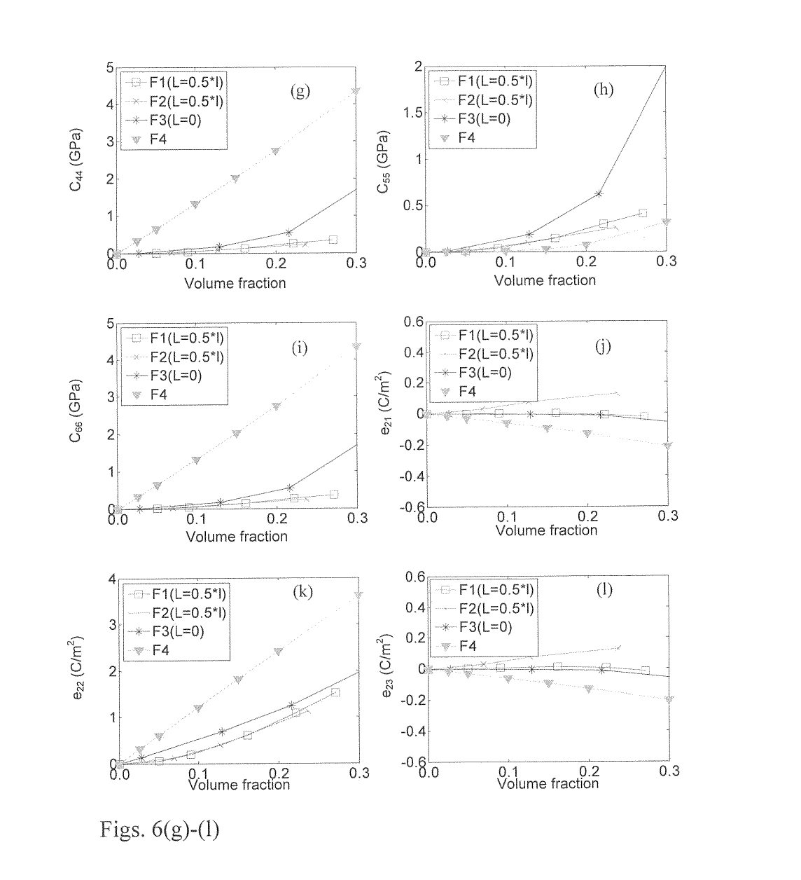

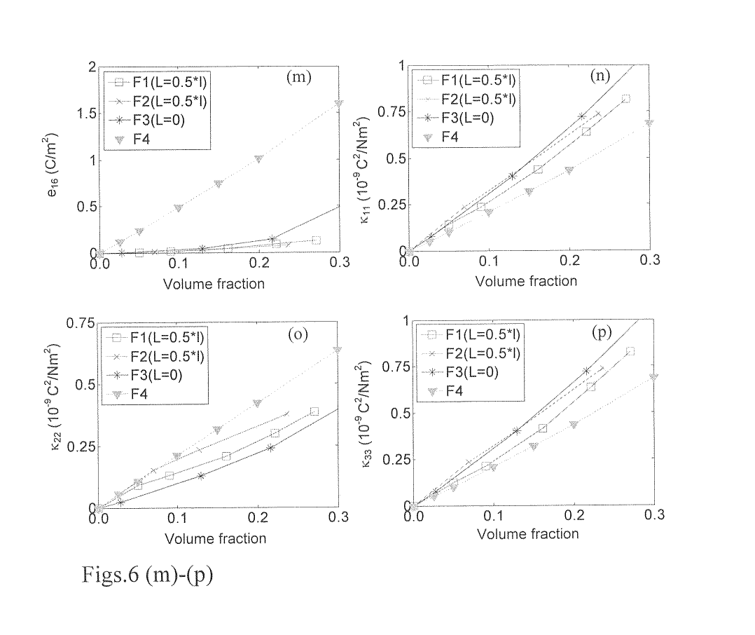

A systematic analysis of the effects of the interconnect geometry and architecture on the effective properties of piezoelectric foam structures was also conducted. Several foam structures with a range of interconnect lengths at a fixed volume fraction were considered and properties benchmarked with those of the foam structures without any interconnects, as shown in FIGS. 6(a)-(p), with FIGS. 6(a)-(i) comparing the fundamental elastic properties of the F1, F2 and F3 type piezoelectric foam structures to the elastic properties of conventional F4 type long-porous piezoelectric materials. FIGS. 6(j)-(m) compare piezoelectric properties of the F1, F2 and F3 type piezoelectric foam structures to piezoelectric properties of conventional F4 type long-porous piezoelectric materials. FIGS. 6(o)-(p) compare dielectric properties of the F1, F2 and F3 type piezoelectric foam structures to dielectric properties of conventional F4 type long-porous piezoelectric materials.

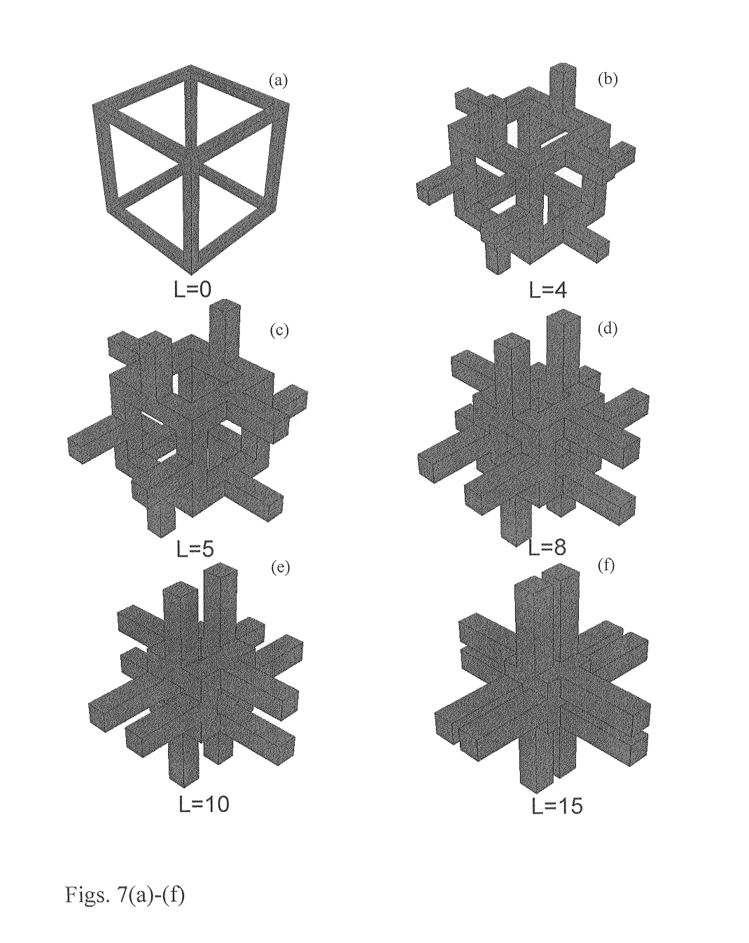

FIGS. 7(a)-7(f) provide schematic representations of closely-packed and sparsely-packed F1 type piezoelectric foam structures of the present invention, for structures having a particular material volume fraction, i.e., 6.33%, and having different interconnect lengths, with FIG. 7(a) showing a piezoelectric foam structure without interconnects, FIG. 7(b) showing a piezoelectric foam structure with an interconnect length=0.4 times an inner cube dimension, FIG. 7(c) showing a piezoelectric foam structure with interconnect length=0.5 times the inner cube dimension, FIG. 7(d) showing a piezoelectric foam structure with interconnect length=0.8 times the inner cube dimension, FIG. 7(e) showing a piezoelectric foam structure with interconnect length=1.0 times the inner cube dimension, and FIG. 7(f) showing a piezoelectric foam structure with interconnect length=1.5 times the inner cube dimension. Foam structures with smaller interconnect lengths, e.g., structures with interconnect lengths less than or equal to 0.5 times the inner cube dimension, are identified as close-packed piezoelectric foam structures and foam structures with larger interconnect lengths, e.g., structure with interconnect lengths greater than 0.5 times the inner cube length, are identified as sparsely-packed piezoelectric foam structures.

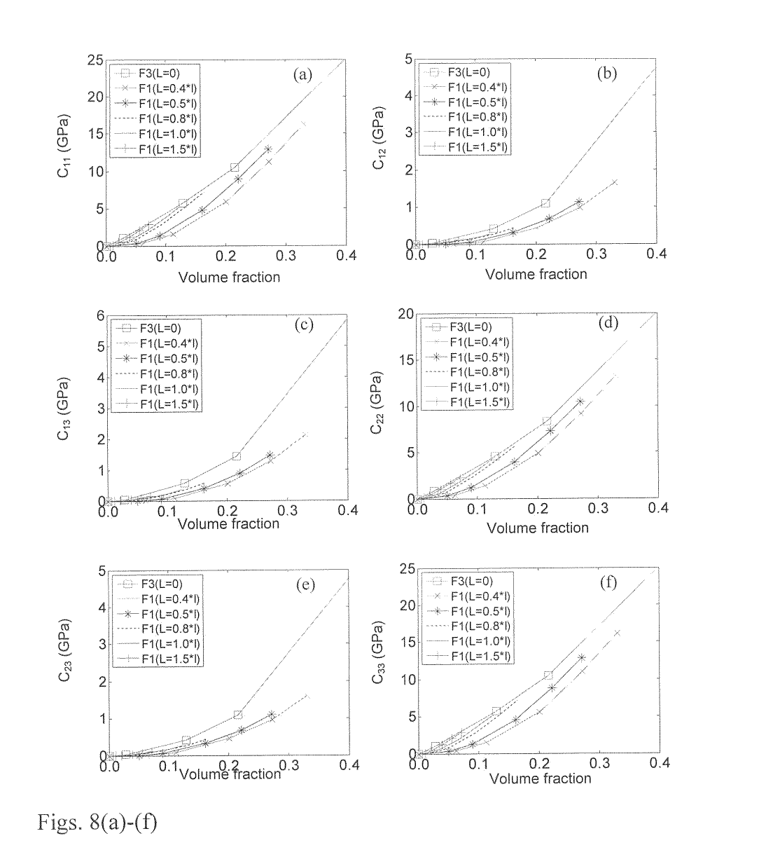

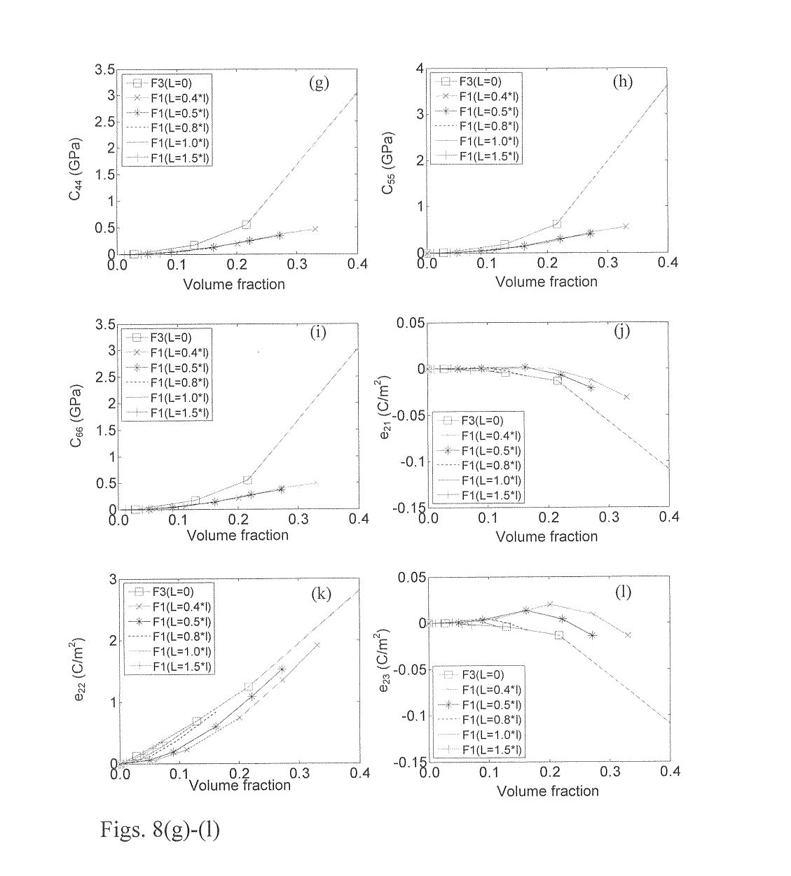

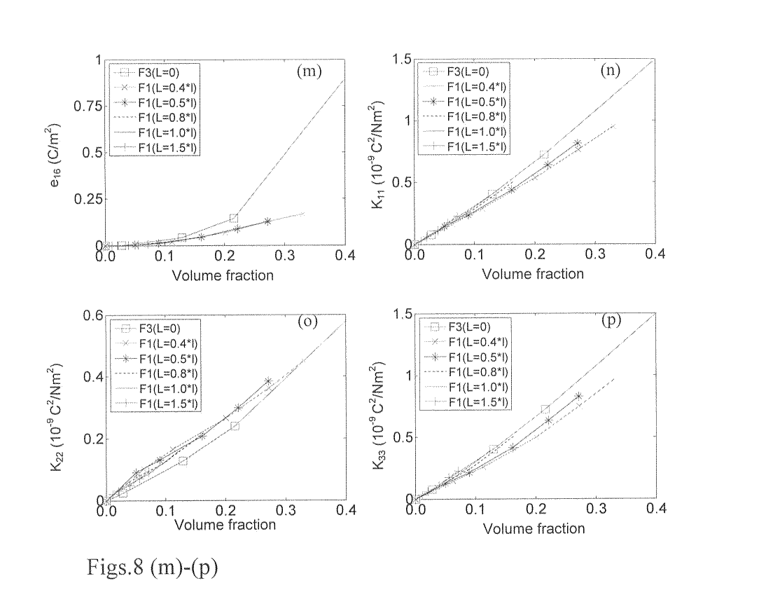

The finite element analysis of a range of foam structures from the close-packed to the sparsely-packed indicates that the fundamental elastic, piezoelectric and dielectric constants generally increase with the interconnect lengths for a wide range of volume fractions resulting in the sparsely-packed structures exhibiting electroelastically stiffer responses compared to the close-packed structures, as shown in FIGS. 8(a)-(p), which show variation of the fundamental elastic (a-i), piezoelectric (j-m), and dielectric (n-o) properties of the F1 type piezoelectric foam structures of the present invention as a function of the interconnect lengths and volume fraction. In FIGS. 8(a)-(j), structures with shorter interconnect lengths, e.g., L=0.4 times 1, are considered as relatively close-packed foams while structures with longer interconnect lengths, e.g., L=1.5 times 1, are considered as relatively sparsely-packed foams, with L being the interconnect length and 1 being the inner cube dimension.

To assess properties of close-packed and sparsely-packed foam structures, it is important to maintain the dimensions of the inner cube of the foam structures constant. Consequently, at a fixed volume fraction, the relatively close-packed foam structures have shorter interconnect lengths and thinner struts, while the relatively sparsely-packed foam structures have longer interconnect lengths and thicker struts. Thus, the higher stiffness observed in the sparsely-packed structures can be directly attributed to the fact that these structures also have higher strut thicknesses which tend to have a dominant influence on the effective properties of these foam structures.

In comparing the properties of the close-packed foam structures and the sparsely-packed structures with those foam structures that do not have any interconnects, i.e., interconnect length equals zero, as shown in FIGS. 8(a)-(p), with the interconnect-free foam structures exhibiting the highest elastic, dielectric and piezoelectric constants. Thus, it is evident that from amongst the various foam structures provided in the present invention, enhancement in the stiffness realized by elimination of ‘weak links,’ i.e., interconnects in the interconnect-free foam structure, is greater than the increase in the stiffness provided by thicker interconnect struts in the sparsely-packed foam structures.

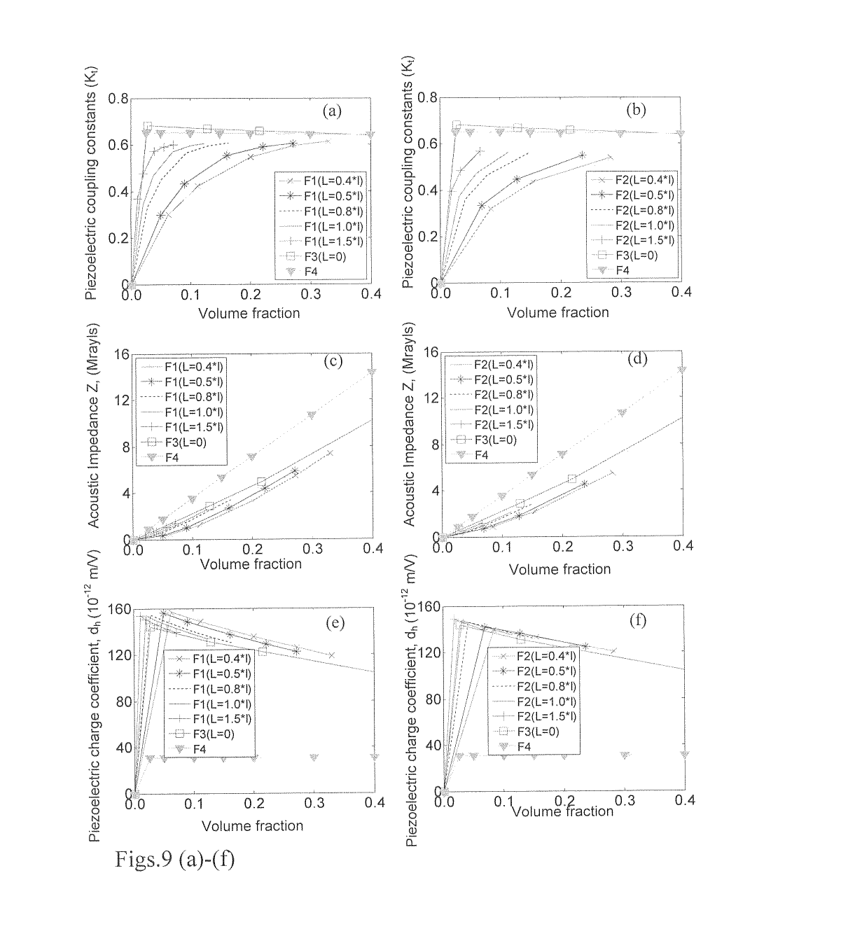

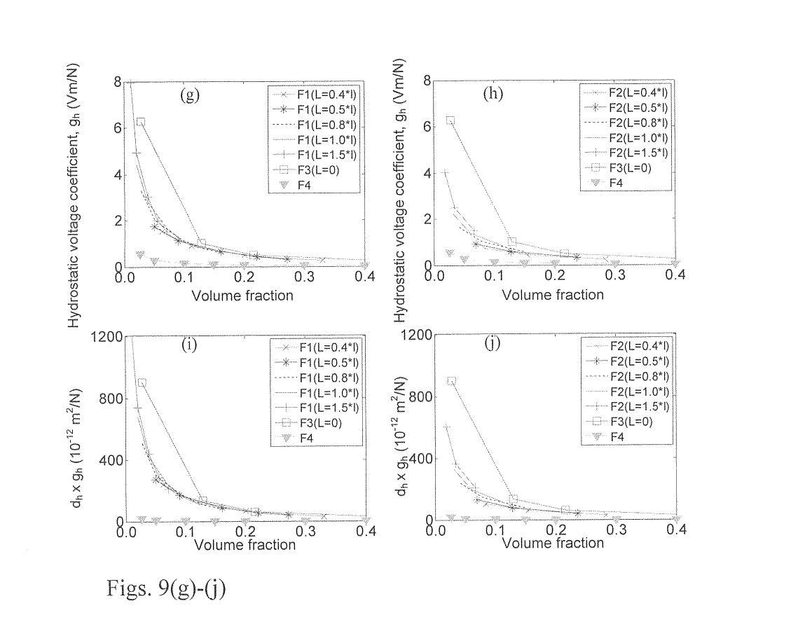

As discussed above, figures of merit are typically invoked in assessing the utility of piezoelectric materials for hydrophone applications. Figures of merit include the piezoelectric coupling constant, acoustic impedance, piezoelectric charge coefficient, and the hydrostatic figure of merit. The present invention provides a method to identify the figures of merit of a wide range of piezoelectric foam structures, with resultant observations provided in FIGS. 9(a)-(j) showing variation of select figures of merit of piezoelectric foam structures F1, F2 and F3 of the present invention compared to conventional long-porous piezoelectric materials F4, with highest piezoelectric coupling constants and the highest acoustic impedance obtained in interconnect-free (3-3) piezoelectric foam structures (F3), while the corresponding figures of merit for the 3-1 long-porous structure are marginally higher. From amongst the foam structures, the sparsely-packed foam structures (with longer and thicker interconnects) tend to exhibit higher coupling constants and acoustic impedance as compared to close-packed foam structures (with shorter and thinner interconnects).

The acoustic impedance of the 3-1 type long-porous piezoelectric structures increase linearly with volume fraction while that of the 3-3 type foam structures tend to be non-linear. The piezoelectric charge coefficients (dₕ), the hydrostatic voltage coefficients (gₕ) and the hydrostatic figures of merit (dₕgₕ) are observed to be significantly higher for the 3-3 type piezoelectric foam structures as compared to the 3-1 type long-porous structures. For example, at about 3% volume fraction, the dₕ, gₕ, and dₕgₕ figures of merit are, respectively, 360%, 1000% and 5000% higher for the interconnect-free foam structure (F3) as compared to that of the 3-1 type long-porous structure (F4). From amongst the 3-3 piezoelectric foam structures, those that are close-packed tend to exhibit higher piezoelectric charge coefficients while the sparsely-packed structures tend to exhibit higher hydrostatic voltage coefficients and hydrostatic figures of merit. The piezoelectric charge coefficients, the hydrostatic voltage coefficients and the hydrostatic figures of merit of the 3-3 type foam structures with asymmetric interconnects (F1) are higher than those of the 3-3 type foam structures with symmetric interconnects (F2).

Overall, the method of the present invention provides 3-3 type piezoelectric foam structures (with or without interconnects) with superior characteristics for piezoelectric applications, i.e., the desired combination of characteristics are enhanced piezoelectric charge coefficients, hydrostatic voltage coefficients and hydrostatic figures of merit without significant loss in the piezoelectric coupling constants or significant increase in acoustic impedance.

### Nano-Indentation Testing

Verification of the piezoelectric foam properties is performed by three-dimensional finite element modeling of nano-indentation that captures the force-depth and charge-depth nano-indentation response. Longitudinal and transverse indentations are selectively applied and responses thereto are used to identify the piezoelectric material poling directions. A method of instrumented indentation involves indenting a substrate material with a conical, spherical or flat indenter, and measuring the force-depth relationship during the loading and the unloading cycle. For piezoelectric materials, depending on electrical boundary conditions introduced into indentation set-up, the electric fields/voltage generated (open loop) or electric charge/current generated (closed loop) in the indentation process is also determined. Analytical modeling of the indentation of transversely isotropic piezoelectric materials with conical, spherical and flat conducting indenter, predict the force (P)-depth (h) and charge (Q)-depth (h) relationships, with Equation (7) relating to conical indentation, Equation (8) relating to spherical indentation, and Equation (9) relating to flat indentation:

$$\begin{matrix}P = \frac{4 {C}_{4} tan θ}{π} {h}^{2} ; Q = \frac{4 {C}_{5} tan θ}{π} {h}^{2} & ( 7 ) \\ P = \frac{8}{3} {C}_{4} {R}^{1 / 2} {h}^{3 / 2} ; Q = \frac{8}{3} {C}_{5} {R}^{1 / 2} {h}^{3 / 2} & ( 8 ) \\ P = 4 {C}_{4} {a}_{0} h ; Q = 4 {C}_{5} {a}_{0} h , & ( 9 )\end{matrix}$$

where θ is a half-apex angle of the conical indenter, R is a radius of the spherical indenter, and aₒ is the width of the flat indenter. Constants C₄ and C₅ are complex functions of the elastic, dielectric and piezoelectric properties of the indented materials.

These analytical models are useful for identifying indentation response of a small group of transversely isotropic piezoelectric materials, with the above-described finite element modeling having broad applicability for characterizing the indentation response of a larger group of piezoelectric materials that are elastically anisotropic. The finite element indentation model shows that the force-depth relationships display a strong dependence on indenter geometry, with a stiffest indentation response observed for indentation with the flat indenter and a most compliant response observed for the conical indenter. Charge-depth relationships obtained for indentation with a conducting indenter also display a strong dependence on the indenter geometry with the maximum charges generated, for a particular indentation depth, being obtained for indentations with a flat indenter.

Using the finite element indentation model, internal stress and electric field distribution are mapped, and regions of mechanical stress and electrical field concentrations are identified and utilized to confirm the enhanced piezoelectric foam properties, and also to detect potential mechanical failures, e.g., cracking, in piezoelectric materials.

While the invention has been shown and described with reference to certain embodiments of the present invention thereof, it will be understood by those skilled in the art that various changes in form and details may be made therein without departing from the spirit and scope of the present invention as defined by the appended claims and equivalents thereof.

What is claimed is:

1. A piezoelectric foam formed of elastically anisotropic materials, the piezoelectric foam comprising:
a unit cell of an elastically anisotropic material having a specified deformation and relative density/volume fraction,
wherein the deformation and relative density/volume fraction is specified by subjecting the unit cell to mechanical and electrical loading conditions, measuring resultant stress and electric displacement field components, capturing a homogeneous coupled response of the unit cell, and computing piezoelectric material constants using the captured response.

2. The piezoelectric foam of claim 1, wherein the unit cell identifies a three-dimensional finite element model.

3. The piezoelectric foam of claim 2, wherein the three-dimensional finite element model of the unit cell includes interconnects having a length 1.5 times an inner cube length over a 3%-35% volume fraction range.

4. The piezoelectric foam of claim 1, wherein compatibility of deformation along a 1-direction across unit-cell boundaries is provided by:
u^{I}−u^{S1}=u^{SS1},u^{J}−u^{S2}=u^{JJ}−u^{SS2},
where u refers to translational and electric potential degrees of freedom, superscripts I, II, J and JJ represent nodes on respective faces of the unit cell, and superscripts S1, SS1, S2 and SS2 represent master nodes for face loading and corner loading conditions.

5. The piezoelectric foam of claim 1, wherein compatibility of deformation along a 2-direction across unit-cell boundaries is provided by:
u^{G}−u^{T1}=u^{GG}−u^{TT1},u^{H}−u^{T2}=u^{HH}−u^{TT2},
where u refers to translational and electric potential degrees of freedom, superscripts G, GG, H and HH represent nodes on respective faces of the unit cell, and superscripts T1, TT1, T2 and TT2 represent master nodes for face loading and corner loading conditions.

6. The piezoelectric foam of claim 1, wherein compatibility of deformation along a 3-direction across unit-cell boundaries is provided by:
u^{K}−u^{U1}=u^{KK}−u^{UU1},u^{L}−u^{U2}=u^{LL}−u^{UU2},
where u refers to translational and electric potential degrees of freedom, superscripts L, LL, K and KK represent the nodes on respective faces of the unit cell, and superscripts U1 and UU1 represent master nodes for face loading and corner loading conditions.

7. A hydrophone having a transducer formed of a piezoelectric foam of elastically anisotropic materials, the piezoelectric foam comprising:
a unit cell of an elastically anisotropic material having a specified deformation and relative density/volume fraction,
wherein the deformation and relative density/volume fraction is specified by subjecting the unit cell to mechanical and electrical loading conditions, measuring resultant stress and electric displacement field components, capturing a homogeneous coupled response of the unit cell, and computing piezoelectric material constants using the captured response.

8. A hydrophone having a transducer formed of a piezoelectric foam having an electromechanical coupled constitutive relationship represented by:
σᵢⱼ=Cᵢⱼₖₗ^{E}∈ₖₗ−eᵢⱼₖEₖ
Dᵢ=eᵢₖₗ∈ₖₗ+κᵢⱼ^{∈}Eⱼ,
where σ and ∈ are second-order stress and strain tensors, respectively, E is an electric field vector, D is an electric displacement vector, C^{E} is a fourth-order elasticity tensor with superscript “E” indicating an elasticity tensor corresponding to measurement of C for a predetermined electric field, e is a third-order coupling tensor, and κ^{∈} is a second-order permittivity tensor.

9. The piezoelectric foam of claim 8, wherein the second-order permittivity tensor κ^{∈} is measured at a predetermined strain.
